(19) United States
(12) Patent Application Publication
(10) Pub. No.: US 2025/0183117 A1
(43) Pub. Date: Jun. 5, 2025

(54) SEMICONDUCTOR DEVICE

(71) Applicant: Mitsubishi Electric Corporation, Tokyo (JP)

(72) Inventors: Kazuki ARATA, Tokyo (JP); Ryuichi ISHII, Tokyo (JP)

(73) Assignee: Mitsubishi Electric Corporation, Tokyo (JP)

(21) Appl. No.: 18/840,211

(22) PCT Filed: Oct. 20, 2022
(86) PCT No.: PCT/JP2022/039068

§ 371 Date: Aug. 21, 2024

(30) Foreign Application Priority Data
May 11, 2022 (JP) 2022-077863

(51) Int. Cl. H01L 23/373; H01L 23/31; H01L 23/538; H01L 25/07

(52) U.S. Cl. CPC H01L 23/3735; H01L 23/538; H01L 25/072; H01L 23/3121

(57) ABSTRACT

A semiconductor device includes: a power module having a plurality of semiconductor elements; and a cooler having a cooling surface to which the power module is thermally connected via a joining member having a solder material. The plurality of semiconductor elements are located at such positions as not to overlap with one another as seen in a direction perpendicular to the cooling surface, the cooling surface has a recessed portion, and the recessed portion is located at such a position as to overlap with the joining member provided between the cooling surface and the power module and as not to overlap with any of the plurality of semiconductor elements, as seen in the direction perpendicular to the cooling surface.

### TECHNICAL FIELD

The present disclosure relates to a semiconductor device.

### BACKGROUND ART

In recent years, the capacities of semiconductor devices mounted with high-power semiconductor elements have been progressively increased. In order to conduct large current through a semiconductor element of a semiconductor device having an increased capacity, heat generated in the semiconductor element needs to be efficiently transmitted to a cooler. In view of this necessity, in such a semiconductor device having an increased capacity, it is required to decrease the thermal resistance of a joining member that is provided between the semiconductor element and the cooler and that connects the structural members to each other.

A configuration of a semiconductor device that achieves decrease in the thermal resistance of a joining member having a solder material has been disclosed (see, for example, Patent Document 1). In the configuration disclosed in Patent Document 1, a plating layer such as a nickel plating or a copper plating is provided on a surface, of a power module, that is to be joined to a cooler. Consequently solder wettability is improved. This improvement achieves; improvement in the reliability in joining between the power module and the cooler; and decrease in the thermal resistance of the joining member.

### CITATION LIST

### Patent Document

Patent Document 1: Japanese Patent No. 6183556

### SUMMARY OF THE INVENTION

### Problem to be Solved by the Invention

In the above Patent Document 1, the solder wettability can be improved since the plating layer is provided on the surface, of the power module, that is to be joined. The semiconductor device provided with the plating layer needs to be subjected to a soldering technique with use of formic acid reduction equipment or a vacuum soldering technique with use of a highly active flux. However, each of the techniques leads to occurrence of variation in the solder wettability with the joining member having the solder material. Occurrence of such variation in the solder wettability leads to generation of a solder void. In particular, in the case of providing a plating layer, gas is generated from an organic component contained in the plating layer at a temperature at which the solder is melted, and, when the gas is not discharged to outside, the gas forms a solder void. When such a solder void is generated between a semiconductor element and the cooler, cooling of the semiconductor element is hindered by the solder void, and the thermal resistance is increased. Consequently, a problem arises in that the quality of the semiconductor device might be decreased.

Considering this problem, an object of the present disclosure is to provide a semiconductor device in which the joining quality of a joining member having a solder material is improved and in which decrease in the thermal resistance of the joining member is realized.

### Means to Solve the Problem

A semiconductor device according to the present disclosure includes: a power module having a plurality of semiconductor elements; and a cooler having a cooling surface to which the power module is thermally connected via a joining member having a solder material. The plurality of semiconductor elements are located at such positions as not to overlap with one another as seen in a direction perpendicular to the cooling surface, the cooling surface has a recessed portion, and the recessed portion is located at such a position as to overlap with the joining member provided between the cooling surface and the power module and as not to overlap with any of the plurality of semiconductor elements, as seen in the direction perpendicular to the cooling surface.

### Effect of the Invention

The semiconductor device according to the present disclosure includes: a power module having a plurality of semiconductor elements; and a cooler having a cooling surface to which the power module is thermally connected via a joining member having a solder material. The plurality of semiconductor elements are located at such positions as not to overlap with one another as seen in a direction perpendicular to the cooling surface, the cooling surface has a recessed portion, and the recessed portion is located at such a position as to overlap with the joining member provided between the cooling surface and the power module and as not to overlap with any of the plurality of semiconductor elements, as seen in the direction perpendicular to the cooling surface. Consequently, the recessed portion serves as a path through which gas generated between the power module and the cooler is discharged to outside at the time of joining the power module and the cooler to each other via the joining member. This path leads to inhibition of generation of a void that remains between the cooler and any of the plurality of semiconductor elements when the joining member is solidified. Therefore, the joining quality of the joining member can be improved, and decrease in the thermal resistance of the joining member can be realized.

### BRIEF DESCRIPTION OF THE DRAWINGS

FIG. 1 is a plan view schematically showing a semiconductor device according to embodiment 1.

FIG. 2 is a sectional view, of the semiconductor device, taken at the sectional position A-A in FIG. 1.

FIG. 3 is a sectional view schematically showing another semiconductor device according to embodiment 1.

FIG. 4 is a sectional view schematically showing a semiconductor device according to embodiment 2.

FIG. 5 is a sectional view schematically showing a semiconductor device according to embodiment 3.

FIG. 6 is a plan view schematically showing a semiconductor device according to embodiment 4.

FIG. 7 is a plan view schematically showing a semiconductor device according to embodiment 5.

FIG. 8 is a sectional view, of the semiconductor device, taken at the sectional position B-B in FIG. 7.

FIG. 9 is a plan view schematically showing another semiconductor device according to embodiment 5.

FIG. 10 is a sectional view schematically showing a semiconductor device according to embodiment 6.

### DESCRIPTION OF EMBODIMENTS

Hereinafter, semiconductor devices according to embodiments of the present disclosure will be described with reference to the drawings. Description will be given while the same or corresponding members and portions in the drawings are denoted by the same reference characters.

### Embodiment 1

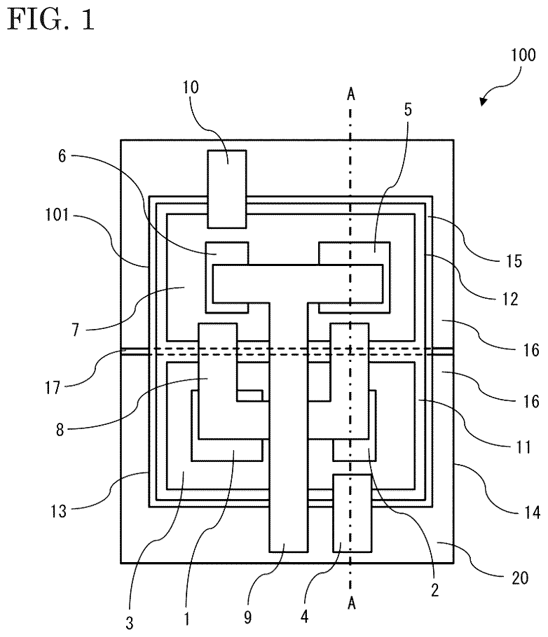

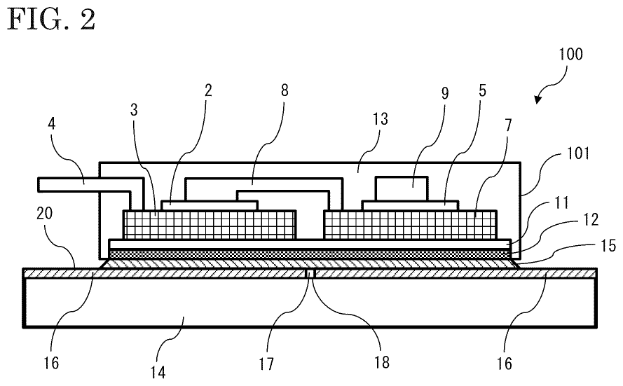

FIG. 1 is a plan view schematically showing a semiconductor device 100 according to embodiment 1. Regarding a sealing resin 13, FIG. 1 shows only the outer shape thereof. FIG. 2 is a sectional view, of the semiconductor device 100, taken at the sectional position A-A in FIG. 1. The semiconductor device 100 is, for example, a device for converting input current from direct current into alternating current or from alternating current into direct current, or converting input voltage into a different voltage.

### Semiconductor Device 100

As shown in FIG. 2, the semiconductor device 100 includes: a power module 101 having a plurality of semiconductor elements; and a cooler 14. The cooler 14 has a cooling surface 20 to which the power module 101 is thermally connected via a joining member 15 having a solder material. In this manner, the power module 101 and the cooler 14 are joined and integrated with each other, to compose the semiconductor device 100. The plurality of semiconductor elements include two semiconductor elements disposed to be adjacent to each other, one of the two semiconductor elements being defined as a first semiconductor element, another one of the two semiconductor elements being defined as a second semiconductor element. As shown in FIG. 1, the power module 101 in the present embodiment has first semiconductor elements 1 and 2 and second semiconductor elements 5 and 6. Although the first semiconductor element is thus composed of the two first semiconductor elements 1 and 2 and the second semiconductor element is thus composed of the two second semiconductor elements 5 and 6, the present disclosure is not limited thereto, and each of the first semiconductor element and the second semiconductor element may be composed of one semiconductor element,

### Power Module 101

The power module 101 has the first semiconductor elements 1 and 2, a first heat spreader 3, the second semiconductor elements 5 and 6, a second heat spreader 7, an insulating member 11, a copper plate 12, and the sealing resin 13. The first semiconductor elements 1 and 2 are each electrically connected to a one-side surface of the first heat spreader 3 via a chip joining member (not shown). The second semiconductor elements 5 and 6 are each electrically connected to a one-side surface of the second heat spreader 7 via a chip joining member (not shown). The second heat spreader 7 is disposed side by side with the first heat spreader 3 with a gap therebetween on a same plane. For each of the chip joining members, for example, a solder or a sintered material that is made from Ag nanoparticles or Cu nanoparticles is used. As shown in FIG. 2, the insulating member 11 has a one-side surface thermally connected to an other-side surface of the first heat spreader 3 and an other-side surface of the second heat spreader 7. The copper plate 12 has a one-side surface thermally connected to an other-side surface of the insulating member 11. The sealing resin 13 covers, in a state where an other-side surface of the copper plate 12 is exposed therefrom, the first heat spreader 3, the second heat spreader 7, the first semiconductor elements 1 and 2, the second semiconductor elements 5 and 6, and the insulating member 11. Heat generated at the time of operation of each of the semiconductor elements is transmitted to the corresponding chip joining member, the corresponding one of the first heat spreader 3 and the second heat spreader 7, the insulating member 11, and the copper plate 12 in this order. Then, the heat is transmitted via the joining member 15 to the cooling surface 20 and dissipated from the cooler 14.

In the present embodiment, the power module 101 has a configuration of a so-called 2-in-1 module, and, as shown in FIG. 1, the first semiconductor element 1 and the second semiconductor element 5 as switching elements and the first semiconductor element 2 and the second semiconductor element 6 as rectifier elements are connected in antiparallel, whereby the power module 101 has two pairs of elements. The configuration of the power module 101 is not limited thereto, and a required number of first semiconductor elements and a required number of second semiconductor elements may be mounted according to use of the semiconductor device 100.

Configurations of lead frames as connection members in the power module 101 will be described. In the present embodiment, the power module 101 has a first lead frame 4, a second lead frame 8, a third lead frame 9, and a fourth lead frame 10. The configurations of the lead frames are not limited thereto, and, in a case where the number of the mounted semiconductor elements is changed as described above, the configurations of the lead frames may be changed according to the number of the mounted semiconductor elements.

The first lead frame 4 has: one end electrically connected to the one-side surface of the first heat spreader 3 via a lead joining member (not shown); and another end exposed from the sealing resin 13. The second lead frame 8 makes electrical connection with a one-side surface of each of the first semiconductor elements 1 and 2 via a corresponding chip joining member (not shown) and makes electrical connection with the one-side surface of the second heat spreader 7 via lead joining members (not shown), to electrically connect these one-side surfaces to each other. The third lead frame 9 has: one end electrically connected to a one-side surface of each of the second semiconductor elements 5 and 6 via a corresponding chip joining member (not shown); and another end exposed from the sealing resin 13. The fourth lead frame 10 has: one end electrically connected to the one-side surface of the second heat spreader 7 via a lead joining member (not shown); and another end exposed from the sealing resin 13. The lead joining members are implemented by, for example, joining members each having a solder material in order to ensure electrical connection between the lead frames and the heat spreaders. Without limitation to joining via the lead joining members, metal joining with use of an ultrasonic wave or a laser, or the like may be employed.

Each of the members of the power module 101 will be described in detail. As each of the first semiconductor element 1 and the second semiconductor element 5, for example, a power semiconductor element which is a semiconductor element for power control such as an insulated-gate bipolar transistor (IGBT) or a metal-oxide-semiconductor field-effect transistor (MOSFET), is used. The present embodiment employs a configuration in which: a switching element having no parasitic diode, such as an IGBT, is used; and a rectifier element such as a flyback diode is provided in parallel. However, without limitation to this configuration, a reverse conducting IGBT (RC-IGBT) in which a switching element and a flyback diode have been integrated with each other may be used. Alternatively, a configuration may be employed in which: a MOSFET is used; and a parasitic diode of the MOSFET is used as a flyback diode. In the case of using an RC-IGBT or the like, each of the first semiconductor element and the second semiconductor element is composed of one semiconductor element.

The first semiconductor elements 1 and 2 and the second semiconductor elements 5 and 6 are formed on semiconductor substrates each formed from a material such as silicon, silicon carbide (SiC), or gallium nitride (GaN), and wide-bandgap semiconductor elements each formed from a material such as silicon carbide having a wider bandgap than silicon can be used. In the case of using such wide-bandgap semiconductor elements, a temporal change amount di/dt of current that is generated in switching can be made larger than that in the case of using elements each formed from silicon. In addition, each of the wide-gap semiconductor elements has a low ON resistance and a high allowable current density, experiences low power loss, and generates little heat, and thus the chip area can be decreased. Since the chip area is decreased, the power module 101 can be downsized.

The first heat spreader 3, the second heat spreader 7, the first lead frame 4, the second lead frame 8, the third lead frame 9, and the fourth lead frame 10 are each formed from any of metal materials having excellent electrical conductivity. Among the metals having excellent electrical conductivity, a copper material is particularly desirable as the material of these spreaders and lead frames from the viewpoint of electrical resistance, processability, cost, and the like. Here, the copper material refers to pure copper or a copper alloy containing copper as a main component.

As the sealing resin 13, a resin having a linear expansion coefficient close to the linear expansion coefficient of each of the first heat spreader 3, the second heat spreader 7, the first lead frame 4, the second lead frame 8, the third lead frame 9, and the fourth lead frame 10 is preferably used so as not to allow increase in thermal degeneration force that is exerted owing to the difference between the linear expansion coefficients. Therefore, since pure copper has a linear expansion coefficient of 16 [ppm/K] to 17 [ppm/K], the linear expansion coefficient of the sealing resin 13 is desirably 15 [ppm/K] to 18 [ppm/K]. The sealing resin 13 is, for example, an inorganic filler that is contained in a thermosetting resin such as an epoxy resin.

The insulating member 11 is required to have heat dissipation properties of transmitting and dissipating, to the cooler 14, heat generated at the time of operation of the first semiconductor elements 1 and 2 and the second semiconductor elements 5 and 6, while ensuring electrical insulation between the semiconductor element side and the copper plate 12 side. The insulating member 11 is obtained by, for example, filling a thermosetting resin with an inorganic filler that has high heat conducting properties and that has insulation properties. The insulating member 11 adheres the copper plate 12 and each of the first heat spreader 3 and the second heat spreader 7 through a thermosetting reaction of the resin. Here, the insulating member 11 is formed from a material having each of heat dissipation properties, insulation properties, and adhesiveness and has a structure in which an inorganic powder filler having high heat conducting properties such as ceramic particles is contained in a thermosetting resin such as an epoxy resin. As the inorganic filler having high heat conducting properties, ceramic particles of aluminum nitride, silicon nitride, boron nitride, aluminum oxide (alumina), silicon oxide (silica), magnesium oxide, zinc oxide, titanium oxide, or the like are suitable. Any of these types of inorganic fillers may be used singly, or two or more of these types of inorganic fillers may be mixed and used.

### Cooler 14

The cooler 14 having the cooling surface 20 to which the power module 101 is thermally connected is required to have high cooling performance. The cooler 14 includes a plurality of heat dissipation fins (not shown) for efficiently dissipating the heat transmitted from the power module 101. The heat dissipation fins are provided on, for example, a portion of the cooler 14 on an opposite side to the power module 101 side. The cooler 14 may be a liquid-cooling-type or air-cooling-type cooler. In the present embodiment, the cooler 14 is implemented by a heatsink made of a metal and having the shape of a flat plate. However, the cooler 14 is not limited thereto and may be a liquid-cooling-type cooler having a flow path in which a cooling liquid flows. The cooler 14 is preferably formed from, for example, any material selected from the group consisting of copper, aluminum, copper alloys, and aluminum alloys. A particularly suitable material of the cooler 14 is aluminum or an aluminum alloy as an aluminum-containing alloy, each of which is lightweight and has excellent processability. In a case where the material of the cooler 14 is aluminum or an aluminum alloy, the weight of the semiconductor device 100 can be decreased. In addition, productivity for the Semiconductor device 100 can be improved.

The other-side surface, of the copper plate 12 of the power module 101, that is exposed from the sealing resin 13 is thermally connected to the cooling surface 20 of the cooler 14 via the joining member 15. The cooling surface 20 of the cooler 14 is required to have high solder wettability in order to solder the power module 101 to the cooling surface 20 via the joining member 15 with a high joining quality. Therefore, the material of the cooler 14 is desirably copper having a solder wettability. However, in a case where the material of a body portion of the cooler 14 is aluminum or an aluminum alloy as described above, it is optimal to provide a plating layer 16 having a solder wettability as the cooling surface 20 of the cooler 14, with copper being used as a material of the plating layer 16. Instead of directly providing the plating layer 16 onto the aluminum or the aluminum alloy, a nickel plating layer (not shown) as a base plating layer may be provided in order to improve close-contact properties in plating and the solder wettability of the surface.

In the present embodiment, the material of the cooler 14 is aluminum or an aluminum alloy, and, as shown in FIG. 2, the plating layer 16 is provided on the power module 101 side of the cooler 14. Therefore, the cooling surface 20 is a surface of the plating layer 16 having a solder wettability. That is, out of joining surfaces at which the power module 101 and the cooler 14 are joined to each other via the joining member 15, one joining surface is the other-side surface of the copper plate 12 and the other joining surface, i.e., the cooling surface 20, is the plating layer 16 provided on the surface of the cooler 14.

### Recessed Portion 17 of Cooling Surface 20

A recessed portion 17, of the cooling surface 20, which is a main portion of the present disclosure will be described. The first semiconductor elements 1 and 2 and the second semiconductor elements 5 and 6 as a plurality of semiconductor elements are located at such positions as not to overlap with one another as seen in a direction perpendicular to the cooling surface 20. The cooling surface 20 has the recessed portion 17. The recessed portion 17 is located at such a position as to overlap with the joining member 15 provided between the cooling surface 20 and the power module 101 and as not to overlap with any of the first semiconductor elements 1 and 2 and the second semiconductor elements 5 and 6, as seen in the direction perpendicular to the cooling surface 20. The recessed portion 17 penetrates the plating layer 16 such that a member on a lower side relative to the plating layer 16 is exposed. The exposed member on the lower side has a lower solder wettability than the plating layer 16. The exposed portion of the member on the lower side is a recessed-portion surface 18. In the present embodiment, the exposed member on the lower side is made of aluminum or an aluminum alloy,

In the case of providing the plating layer 16, gas is generated from an organic component contained in the plating layer 16 at a temperature at which the solder is melted, and, when the gas is not discharged to outside, the gas forms a solder void. When such a solder void is generated between any of the semiconductor elements and the cooler 14, cooling of the semiconductor element is hindered by the solder void, and the thermal resistance is increased. Consequently, the quality of the semiconductor device 100 is decreased. Cases where such a void is generated are not limited to the case where a void is generated from the plating layer 16, and also include a case where: a gap is present between the joining member 15 and another member at the time of melting the joining member 15; and a void is caused by the portion at the gap.

However, since the recessed portion 17 is located at such a position, on the cooling surface 20, as not to overlap with any of the first semiconductor elements 1 and 2 and the second semiconductor elements 5 and 6, the recessed portion 17 serves as a path through which gas generated between the power module 101 and the cooler 14 is discharged to outside at the time of joining the power module 101 and the cooler 14 to each other via the joining member 15. Consequently, even when a solder void is generated, the solder void is eliminated by the discharge through the recessed portion 17 to outside. Since the solder void is eliminated by the discharge through the recessed portion 17 to outside, it is possible to inhibit generation of a void that remains between the cooler 14 and any of the first semiconductor elements 1 and 2 and the second semiconductor elements 5 and 6 when the joining member 15 is solidified. Since generation of a void that remains between the cooler 14 and any of the first semiconductor elements 1 and 2 and the second semiconductor elements 5 and 6 is inhibited, the interval between the cooler 14 and each of the first semiconductor elements 1 and 2 and the second semiconductor elements 5 and 6 is filled with the joining member 15 and the plating layer 16. Therefore, the joining quality of the joining member 15 having the solder material can be improved, and decrease in the thermal resistance of the joining member 15 can be realized. In addition, since the interval between the cooler 14 and each of the first semiconductor elements 1 and 2 and the second semiconductor elements 5 and 6 is filled with the joining member 15 and the plating layer 16, heat generated in each of the semiconductor elements can be efficiently transmitted to the cooler 14.

In the present embodiment, the recessed portion 17 is located, between the first heat spreader 3 and the second heat spreader 7, at such a position as not to overlap with either of the first heat spreader 3 and the second heat spreader 7 as seen in the direction perpendicular to the cooling surface 20. In such a configuration, the recessed portion 17 is not present between the cooler 14 and either of the first heat spreader 3 and the second heat spreader 7, and the interval between the cooler 14 and each of the first heat spreader 3 and the second heat spreader 7 is filled with the joining member 15 and the plating layer 16. Therefore, not only heat generated in each of the semiconductor elements but also heat generated in each of the lead frames and the heat spreaders can be efficiently transmitted to the cooler 14. The location of the recessed portion 17 is not limited thereto, and the recessed portion 17 may be located in another region as long as: hindrance, to transmission of heat, by the recessed portion 17 is inhibited; and the region is at such a position as not to overlap with any of the first semiconductor elements 1 and 2 and the second semiconductor elements 5 and 6. Even in a case where the recessed portion 17 is located in another region, decrease in the thermal resistance of the joining member 15 and inhibition of a solder void can be realized.

In the present embodiment, the exposed member on the lower side is made of aluminum or an aluminum alloy and has a lower solder wettability than the plating layer 16. In such a configuration, the joining member 15 and the recessed-portion surface 18 are not joined to each other in the recessed portion 17, whereby a path through which gas is discharged to outside can be assuredly formed in the recessed portion 17.

In the present embodiment, the recessed portion 17 is a groove extending outward of the joining member 15 provided between the cooling surface 20 and the power module 101 as seen in the direction perpendicular to the cooling surface 20. In such a configuration, since the recessed portion 17 has a portion extending outward of the joining member 15, gas can be easily discharged to outside. Without limitation to the configuration in which the recessed portion 17 is located so as to extend outward of the joining member 15, the recessed portion 17 may be located merely inward of the joining member 15. In a case where the recessed portion 17 is located inward of the joining member 15, gas cannot be discharged to outside but can be discharged into the recessed portion 17. In addition, in the case where the recessed portion 17 is located merely inward of the joining member 15, water, foreign matter, or the like can be inhibited from entering the inside of the semiconductor device 100 from outside through the recessed portion 17.

An example of a method for forming the recessed portion 17 in the cooler 14 will be described. The plating layer 16 is provided on the entirety of the cooler 14, and then a portion, of the plating layer 16, in such a region as to be formed as the recessed portion 17 is cut and removed, whereby the recessed portion 17 can be formed. By thus forming the recessed portion 17, the recessed portion 17 can be easily formed at low cost. In the present embodiment, the recessed portion 17 penetrates the plating layer 16 such that the member on the lower side relative to the plating layer 16 is exposed, and, by employing this forming method, the recessed portion 17 can be easily formed, whereby productivity for the semiconductor device 100 can be improved. The method for forming the recessed portion 17 is not limited thereto and may be a method that includes: masking a portion at which the recessed portion 17 is to be formed at the time of plating; and plating portions of the cooler 14 excluding the portion at which the recessed portion 17 is to be formed.

In the present embodiment, the material of the cooler 14 is aluminum or an aluminum alloy, and the plating layer 16 is provided on the power module 101 side of the cooler 14. However, without limitation thereto, the material of the cooler 14 may be copper or a copper alloy, and a plating layer 16 having nickel or tin may be provided on the power module 101 side of the cooler 14.

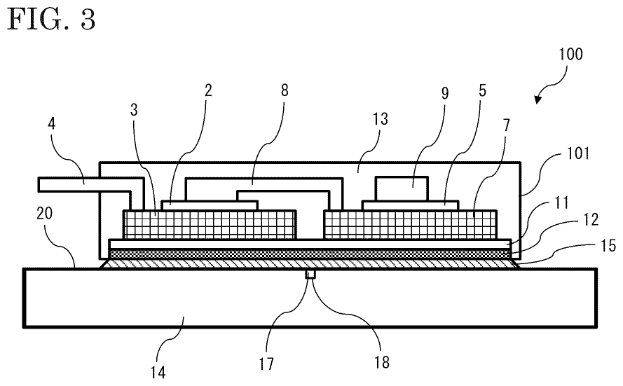

In the case where the material of the cooler 14 is copper or a copper alloy, the recessed portion 17 may be provided in the cooling surface 20 which is the surface on the power module 101 side of the cooler 14 made of the copper or the copper alloy without providing the plating layer 16, as shown in FIG. 3. FIG. 3 is a sectional view schematically showing another semiconductor device 100 according to embodiment 1 and shows a cross section, of the other semiconductor device 100, taken at the same position as that in FIG. 2. In this configuration, the plating layer 16 is not provided, and thus generation of gas from the plating layer 16 does not occur. However, there is also a case where: a gap is present between the joining member 15 and another member at the time of melting the joining member 15; and a void is caused by the portion at the gap. This case is addressed, i.e., such a void can be eliminated through discharge to outside from the recessed portion 17. An aluminum layer may be formed on the recessed-portion surface 18 in the recessed portion 17 through sputtering or the like in order to assuredly form, in the recessed portion 17, a path for eliminating a void through discharge.

As described above, the semiconductor device 100 according to embodiment 1 includes: the power module 101 having the first semiconductor elements 1 and 2 and the second semiconductor elements 5 and 6; and the cooler 14 having the cooling surface 20 to which the power module 101 is thermally connected via the joining member 15 having the solder material. The first semiconductor elements 1 and 2 and the second semiconductor elements 5 and 6 are located at such positions as not to overlap with one another as seen in the direction perpendicular to the cooling surface 20, the cooling surface 20 has the recessed portion 17, and the recessed portion 17 is located at such a position as to overlap with the joining member 15 provided between the cooling surface 20 and the power module 101 and as not to overlap with any of the first semiconductor elements 1 and 2 and the second semiconductor elements 5 and 6, as seen in the direction perpendicular to the cooling surface 20. Consequently, the recessed portion 17 serves as a path through which gas generated between the power module 101 and the cooler 14 is discharged to outside at the time of joining the power module 101 and the cooler 14 to each other via the joining member 15. This path leads to inhibition of generation of a void that remains between the cooler 14 and any of the first semiconductor elements 1 and 2 and the second semiconductor elements 5 and 6 when the joining member 15 is solidified. Therefore, the joining quality of the joining member 15 can be improved, and decrease in the thermal resistance of the joining member 15 can be realized.

There is a case where: the power module 101 has the first heat spreader 3 having a one-side surface to which the first semiconductor elements 1 and 2 are electrically connected, and the second heat spreader 7 disposed side by side with the first heat spreader 3 with a gap therebetween on a same plane, the second heat spreader 7 having a one-side surface to which the second semiconductor elements 5 and 6 are electrically connected; and the recessed portion 17 is located, between the first heat spreader 3 and the second heat spreader 7, at such a position as not to overlap with either of the first heat spreader 3 and the second heat spreader 7 as seen in the direction perpendicular to the cooling surface 20. In this case, the recessed portion 17 is not present between the cooler 14 and either of the first heat spreader 3 and the second heat spreader 7, and thus not only heat generated in each of the semiconductor elements but also heat generated in each of the lead frames and the heat spreaders can be efficiently transmitted to the cooler 14.

In a case where the cooling surface 20 is a surface of the plating layer 16 having a solder wettability and the recessed portion 17 penetrates the plating layer 16 such that a member on a lower side relative to the plating layer 16 is exposed, the power module 101 can be soldered to the cooler 14 with a high joining quality, and the recessed portion 17 can be easily formed at low cost.

In a case where the exposed member on the lower side has a lower solder wettability than the plating layer 16, the joining member 15 and the recessed-portion surface 18 are not joined to each other in the recessed portion 17, whereby a path through which gas is discharged to outside can be assuredly formed in the recessed portion 17. In a case where the exposed member on the lower side is made of aluminum or an aluminum alloy, the weight of the semiconductor device 100 can be decreased, and productivity for the semiconductor device 100 can be improved.

In a case where the recessed portion 17 is a groove extending outward of the joining member 15 provided between the cooling surface 20 and the power module 101 as seen in the direction perpendicular to the cooling surface 20, the recessed portion 17 has a portion extending outward of the joining member 15, and thus gas can be easily discharged to outside.

### Embodiment 2

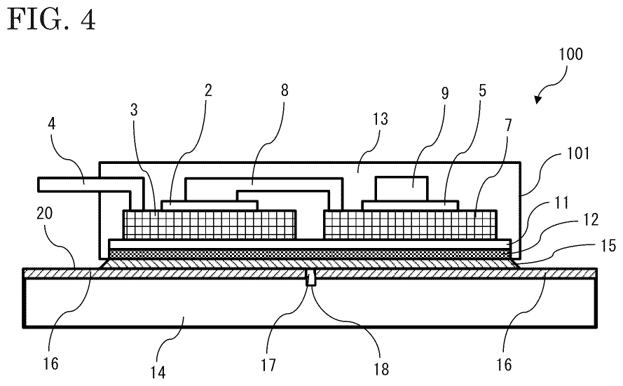

A semiconductor device 100 according to embodiment 2 will be described. FIG. 4 is a sectional view schematically showing the semiconductor device 100 according to embodiment 2 and is a sectional view, of the semiconductor device 100, taken at the same position as that in FIG. 2. The semiconductor device 100 according to embodiment 2 has a configuration in which the sectional shape of a recessed portion 17 differs from that in embodiment 1.

The recessed portion 17 is formed also in the exposed member on the lower side. The recessed-portion surface 18 in the recessed portion 17 is further shifted to the cooler 14 side from a portion on the cooler 14 side of the plating layer 16. In such a configuration, the sectional area of the recessed portion 17 can be made larger than the sectional area of the recessed portion 17 described in embodiment 1. Since the sectional area of the recessed portion 17 is made larger, gas generated at the time of joining the power module 101 and the cooler 14 to each other via the joining member 15 can be more efficiently discharged to outside.

In the present embodiment, the sectional shape of the recessed portion 17 is a rectangular shape. However, the sectional shape of the recessed portion 17 is not limited to a rectangular shape. The recessed portion 17 only has to have a function of a path through which gas generated between the power module 101 and the cooler 14 is discharged to outside. Thus, the sectional shape of the recessed portion 17 may be a shape such as a V shape or a U shape.

An example of a method for forming the recessed portion 17 in the cooler 14 will be described. The plating layer 16 is provided on the entirety of the cooler 14, and then portions, of the plating layer 16 and the cooler 14, in such a region as to be formed as the recessed portion 17 are cut and removed, whereby the recessed portion 17 can be formed. By thus forming the recessed portion 17, the recessed portion 17 can be easily formed at low cost. The method for forming the recessed portion 17 is not limited thereto and may be a method that includes: providing, in advance, a groove that is to serve as the recessed portion 17, the groove being provided at a portion, of the cooler 14, at which the recessed portion 17 is to be formed; masking the groove portion at which the recessed portion 17 is to be formed at the time of plating; and plating portions of the cooler 14 excluding the portion at which the recessed portion 17 is to be formed.

### Embodiment 3

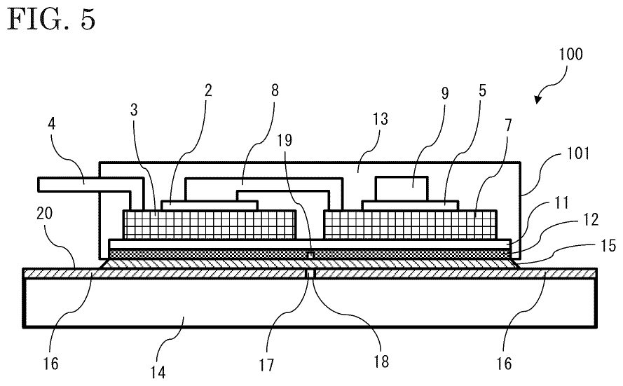

A semiconductor device 100 according to embodiment 3 will be described. FIG. 5 is a sectional view schematically showing the semiconductor device 100 according to embodiment 3 and is a sectional view, of the semiconductor device 100, taken at the same position as that in FIG. 2. The semiconductor device 100 according to embodiment 3 has a configuration in which a module-side recessed portion 19 is provided in the power module 101.

A surface on the joining member 15 side of the power module 101 has the module-side recessed portion 19. The module-side recessed portion 19 is located at such a position as to overlap with the joining member 15 provided between the cooling surface 20 and the power module 101 and as not to overlap with any of the plurality of semiconductor elements, as seen in the direction perpendicular to the cooling surface 20. In the present embodiment, the module-side recessed portion 19 is located between: the first semiconductor elements 1 and 2; and the second semiconductor elements 5 and 6.

The module-side recessed portion 19 is a path through which gas generated at the time of joining the power module 101 and the cooler 14 to each other via the joining member 15 is discharged to outside. In such a configuration, the path through which gas is discharged to outside can be further provided in addition to the recessed portion 17. Since the path through which gas is discharged to outside is further formed, gas generated at the time of joining the power module 101 and the cooler 14 to each other can be more efficiently discharged to outside than in embodiment 1.

In the present embodiment, the module-side recessed portion 19 is located on the power module 101 side relative to the recessed portion 17. However, the location of the module-side recessed portion 19 is not limited thereto. As necessary, the module-side recessed portion 19 may be located at a position different from the above position. Also, the number of the module-side recessed portions 19 is not limited to one, and a plurality of the module-side recessed portions 19 may be provided.

In the present embodiment, the sectional shape of the module-side recessed portion 19 is a rectangular shape, However, the sectional shape of the module-side recessed portion 19 is not limited to a rectangular shape. The module-side recessed portion 19 only has to have a function of a path through which gas generated between the power module 101 and the cooler 14 is discharged to outside. Thus, the sectional shape of the module-side recessed portion 19 may be a shape such as a V shape or a U shape.

In the present embodiment, an example in which the module-side recessed portion 19 is provided to the semiconductor device 100 described in embodiment 1 has been described. However, without limitation thereto, the module-side recessed portion 19 may be provided to the semiconductor device 100 described in embodiment 2.

### Embodiment 4

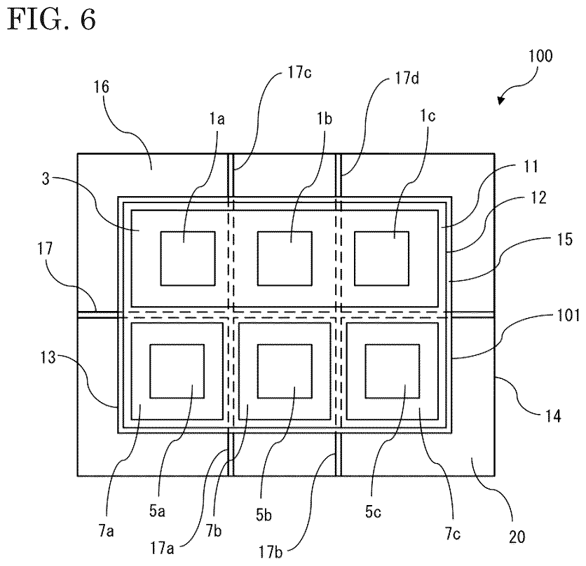

A semiconductor device 100 according to embodiment 4 will be described. FIG. 6 is a plan view schematically showing the semiconductor device 100 according to embodiment 4. Regarding the sealing resin 13, FIG. 6 shows only the outer shape thereof. FIG. 6 does not show the lead frames. The semiconductor device 100 according to embodiment 4 has a configuration in which a plurality of the semiconductor elements and a plurality of the recessed portions are provided.

In the present embodiment, the power module 101 has a configuration of a so-called 6-in-1 power module. On the upper side in FIG. 6, first semiconductor elements 1a, 1b, and 1c are arranged on the first heat spreader 3 with gaps between the first semiconductor elements 1a, 1b, and 1c in the lateral direction of the first heat spreader 3. On the lower side in FIG. 6, second semiconductor elements 5a, 5b, and 5c are respectively provided on second heat spreaders 7a, 7b, and 7c. The first semiconductor elements 1a, 1b, and 1c are provided at and around the centers of respective three portions obtained by trisecting the first heat spreader 3 in the lateral direction.

Arrangement of the recessed portions will be described. The recessed portion 17 is located, between the first heat spreader 3 and the second heat spreaders 7a, 7b, and 7c, at such a position as not to overlap with any of the first heat spreader 3 and the second heat spreaders 7a, 7b, and 7c as seen in the direction perpendicular to the cooling surface 20. A recessed portion 17a is located, between the second heat spreaders 7a and 7b, at such a position as not to overlap with either of the second heat spreaders 7a and 7b as seen in the direction perpendicular to the cooling surface 20. A recessed portion 17b is located, between the second heat spreaders 7b and 7c, at such a position as not to overlap with either of the second heat spreaders 7b and 7c as seen in the direction perpendicular to the cooling surface 20. A recessed portion 17c is located, between the first semiconductor elements 1a and 1b, at such a position as not to overlap with either of the first semiconductor elements 1a and 1b as seen in the direction perpendicular to the cooling surface 20. A recessed portion 17d is located, between the first semiconductor elements 1b and 1c, at such a position as not to overlap with either of the first semiconductor elements 1b and 1c as seen in the direction perpendicular to the cooling surface 20.

In the present embodiment, without limitation to positions each of which is a position between the corresponding semiconductor elements and is a position between the corresponding heat spreaders, recessed portions are provided also at positions each of which is not a position between any of the heat spreaders but is a position between the corresponding semiconductor elements. In a case where the semiconductor elements are arranged with wide gaps therebetween in this manner, recessed portions are provided also at positions each of which is not a position between any of the heat spreaders but is a position between the corresponding semiconductor elements, whereby gas generated at the time of joining the power module 101 and the cooler 14 to each other via the joining member 15 can be more efficiently discharged to outside.

The arrangement of the recessed portions is not limited to the arrangement shown in FIG. 6 and may be a different arrangement as long as each of the recessed portions is located at such a position as to overlap with the joining member 15 provided between the cooling surface 20 and the power module 101 and as not to overlap with any of the plurality of semiconductor elements, as seen in the direction perpendicular to the cooling surface 20. In the case of employing a different arrangement, decrease in the thermal resistance of the joining member 15 and inhibition of a solder void can be realized.

In the present embodiment, the recessed portions 17, 17a, 17b, 17c, and 17d extend outward of the joining member 15 provided between the cooling surface 20 and the power module 101 as seen in the direction perpendicular to the cooling surface 20. Without limitation to the configuration in which the recessed portion 17 is located so as to extend outward of the joining member 15, the recessed portion 17 may be located merely inward of the joining member 15. In a case where the recessed portions 17, 17a, 17b, 17c, and 17d are located inward of the joining member 15, gas cannot be discharged to outside but can be discharged into the recessed portions 17, 17a, 17b, 17c, and 17d. In addition, in the case where the recessed portions 17, 17a, 17b, 17c, and 17d are located merely inward of the joining member 15, water, foreign matter, or the like can be inhibited from entering the inside of the semiconductor device 100 from outside through the recessed portions 17, 17a, 17b, 17c, and 17d.

### Embodiment 5

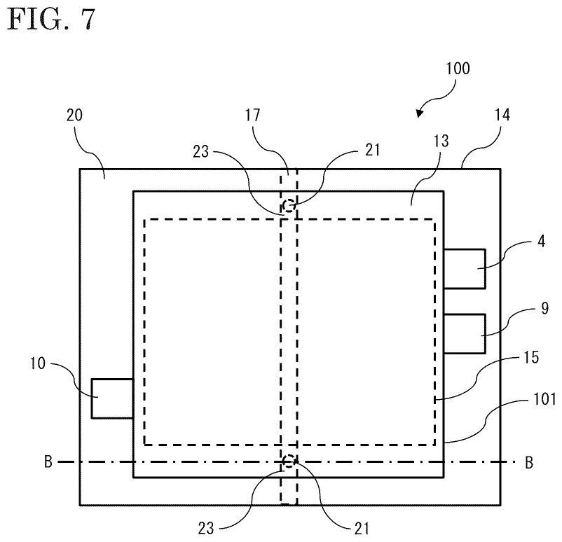

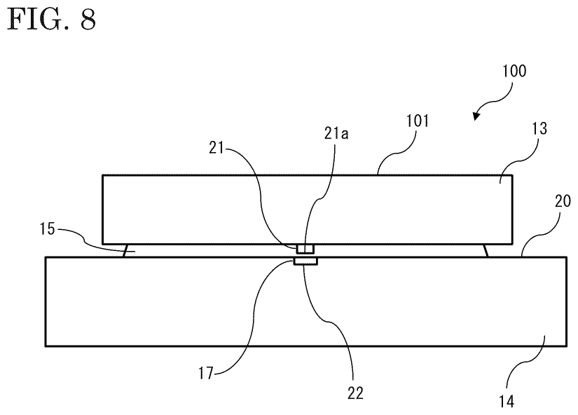

Semiconductor devices 100 according to embodiment 5 will be described. FIG. 7 is a plan view schematically showing a semiconductor device 100 according to embodiment 5, and FIG. 8 is a sectional view, of the semiconductor device 100, taken at the sectional position B-B in FIG. 7. The semiconductor device 100 according to embodiment 5 has a configuration in which the power module 101 has protruding portions 21.

In the present embodiment, as shown in FIG. 7, an outer periphery portion of a gap between the cooling surface 20 and the power module 101 has non-joined regions 23 as regions in which the joining member 15 is not provided. The recessed portion 17 extends, from a region in which the joining member 15 is provided, to the non-joined regions 23 as seen in the direction perpendicular to the cooling surface 20. In the present embodiment, the recessed portion 17 is provided also in portions, of the cooling surface 20, that do not overlap with the power module 101 as seen in the direction perpendicular to the cooling surface 20. The power module 101 has, in the non-joined regions 23, the protruding portions 21 protruding to the recessed portion 17 side. In the present embodiment, one protruding portion 21 is provided in each of two non-joined regions 23 facing the recessed portion 17. A plurality of the protruding portions 21 may be provided in each of the non-joined regions 23.

As shown in FIG. 8, each of the protruding portions 21 is a portion, of the sealing resin 13 sealing the parts composing the power module 101, that protrudes to the recessed portion 17 side. The protruding portions 21 are produced simultaneously with sealing of the parts composing the power module 101. The method for producing the protruding portions 21 is not limited thereto. For example, parts each made of a metal material or the like may be, together with the parts composing the power module 101, sealed so as to have portions protruding from the sealing resin 13, and these portions may be used as the protruding portions 21. Alternatively, the parts to serve as the protruding portions 21 may be attached to portions, of the sealing resin 13, in the non-joined regions 23 facing the recessed portion 17. In a case where each of the protruding portions 21 is made of a metal having a high solder wettability and is provided to be adjacent to the joining member 15, the metal and the solder are wet after gas is discharged, whereby foreign matter such as water can be inhibited from entering the inside of the recessed portion 17. In a case where the protruding portions 21 are produced from the sealing resin 13 simultaneously with sealing of the parts composing the power module 101, no other parts to serve as the protruding portions 21 are necessary, whereby productivity for the semiconductor device 100 can be improved. Therefore, the protruding portions 21 are desirably produced from the sealing resin 13.

By thus providing the protruding portions 21, it is possible to inhibit a cleaning liquid from entering the interval between the power module 101 and the recessed portion 17 in a cleaning step after the joining, while maintaining the function of efficiently discharging, to outside, gas generated at the time of joining the power module 101 and the cooler 14 to each other via the joining member 15. Since entry of a cleaning liquid is inhibited, a cleaning liquid can be prevented from adhering on a surface of the power module 101 as a result of ejection of the cleaning liquid from between the power module 101 and the recessed portion 17 during subsequent drying. Since a cleaning liquid can be prevented from adhering on the surface of the power module 101, creepage insulation properties of the power module 101 can be enhanced.

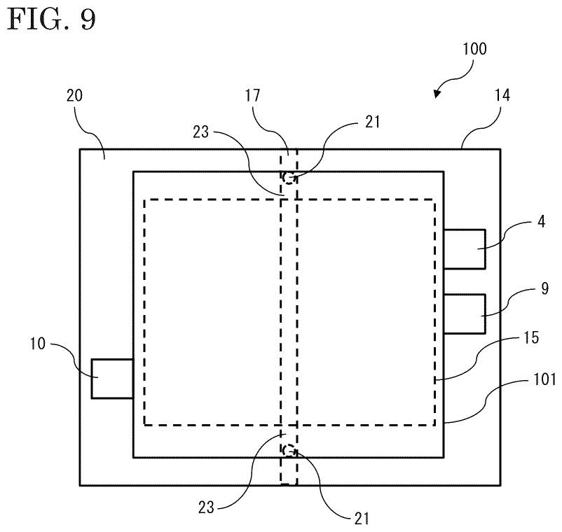

Although each of the protruding portions 21 in FIG, 7 is located at a center portion of the corresponding non-joined region 23 in the direction in which the recessed portion 17 extends, the location of the protruding portion 21 is not limited to the center portion of the non-joined region 23. As shown in FIG. 9, the protruding portion 21 may be located at an outer end portion of the non-joined region 23. FIG. 9 is a plan view schematically showing another semiconductor device 100 according to embodiment 5. In such a configuration, the region that allows entry of a cleaning liquid can be decreased, whereby the creepage insulation performance of the power module 101 can be further enhanced. As the location of the protruding portion 21 becomes closer to the outer end portion of the non-joined region 23, the effect of decreasing the region that allows entry of a cleaning liquid becomes higher.

In the present embodiment, as shown in FIG. 8, the protruding portion 21 has a height higher than a depth of the recessed portion 17, and a gap is present between the protruding portion 21 and an inner surface of the recessed portion 17. FIG. 8 shows the sectional shapes of the protruding portion 21 and the recessed portion 17. A cleaning liquid can be inhibited from entering the interval between the power module 101 and the recessed portion 17, by merely providing the protruding portion 21. However, in the case where the protruding portion 21 has a height higher than the depth of the recessed portion 17 and a gap is present between the protruding portion 21 and the inner surface of the recessed portion 17, the effect of inhibiting entry of a cleaning liquid can be further improved. A specific dimension is as follows. That is, a dimension between a top 21a of the protruding portion 21 and a bottom 22 of the recessed portion is smaller than 0.22 mm. With this dimension, although entry of water occurs, water is not discharged to outside. Consequently, insulation properties can be enhanced. Furthermore, when the dimension between the top 21a of the protruding portion 21 and the bottom 22 of the recessed portion is 0.08 mm or smaller, entry of water can be prevented, whereby a higher effect can be obtained in relation to enhancement of the insulation properties.

In the present embodiment, as shown in FIG. 8, the vertical sectional shape of the protruding portion 21 is a rectangular shape. However, the vertical sectional shape of the protruding portion 21 is not limited to a rectangular shape. The protruding portion 21 only has to have the function of inhibiting entry of a cleaning liquid from outside, while maintaining the function of the path through which gas generated between the power module 101 and the cooler 14 is discharged to outside. Thus, the vertical sectional shape of the protruding portion 21 may be, for example, a shape such as a V shape or a U shape.

In the present embodiment, as shown in FIG. 7, the horizontal sectional shape of the protruding portion 21 is a circular shape. However, the horizontal sectional shape of the protruding portion 21 is not limited to a circular shape. The protruding portion 21 only has to have the function of inhibiting entry of a cleaning liquid from outside, while maintaining the function of the path through which gas generated between the power module 101 and the cooler 14 is discharged to outside. Thus, the horizontal sectional shape of the protruding portion 21 may be, for example, a shape such as a quadrangular shape or a hexagonal shape. In a case where the top 21a of the protruding portion 21 is located on an inner side of the recessed portion 17, the horizontal sectional shape of the protruding portion 21 is such a shape as to have a gap between each of side walls of the recessed portion 17 and the corresponding side wall of the protruding portion 21, and, as the gap becomes smaller, the effect of inhibiting entry of a cleaning liquid can be made higher.

### Embodiment 6

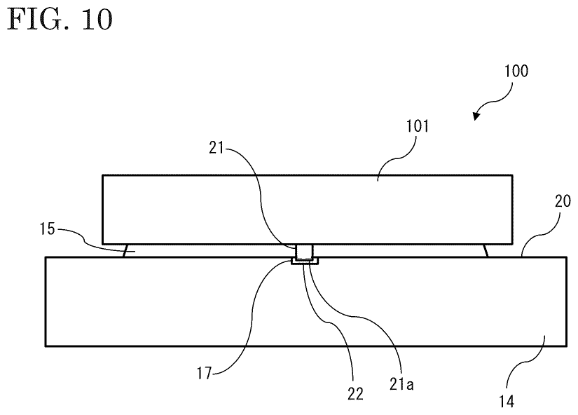

A semiconductor device 100 according to embodiment 6 will be described. FIG. 10 is a sectional view schematically showing the semiconductor device 100 according to embodiment 6 and is a sectional view, of the semiconductor device 100, taken at the same position as that in FIG. 8. The semiconductor device 100 according to embodiment 6 has a configuration in which the position of the top 21a of each of the protruding portions 21 is defined.

The top 21a of the protruding portion 21 is located on the inner side of the recessed portion 17, and a gap is present between the protruding portion 21 and the inner surface of the recessed portion 17. In such a configuration, the distance between the top 21a of the protruding portion 21 and the bottom 22 of the recessed portion can be shortened. Since the distance between the top 21a of the protruding portion 21 and the bottom 22 of the recessed portion is shortened, it is possible to further improve the effect of inhibiting entry of a cleaning liquid, while maintaining the function of the path through which gas generated between the power module 101 and the cooler 14 is discharged to outside. Since the effect of inhibiting entry of a cleaning liquid is further improved, the creepage insulation properties of the power module 101 can be further enhanced.

The present embodiment is also such that, similar to embodiment 5, the protruding portion 21 has a height higher than the depth of the recessed portion 17, and a gap is present between the protruding portion 21 and the inner surface of the recessed portion 17. Thus, the present embodiment has the same advantageous effects as those in embodiment 5. Although the vertical sectional shape of the protruding portion 21 is a rectangular shape in the present embodiment, the vertical sectional shape of the protruding portion 21 is not limited to a rectangular shape. The vertical sectional shape of the protruding portion 21 may be, for example, a shape such as a V shape or a U shape.

Although the disclosure is described above in terms of various exemplary embodiments and implementations, it should be understood that the various features, aspects, and functionality described in one or more of the individual embodiments are not limited in their applicability to the particular embodiment with which they are described, but instead can be applied, alone or in various combinations to one or more of the embodiments of the disclosure.

It is therefore understood that numerous modifications which have not been exemplified can be devised without departing from the scope of the specification of the present disclosure. For example, at least one of the constituent components may be modified, added, or eliminated. At least one of the constituent components mentioned in at least one of the preferred embodiments may be selected and combined with the constituent components mentioned in another preferred embodiment.

Hereinafter, modes of the present disclosure are summarized as additional notes.

### Additional Note 1

A semiconductor device comprising:

a power module having a plurality of semiconductor elements; and

a cooler having a cooling surface to which the power module is thermally connected via a joining member having a solder material, wherein

the plurality of semiconductor elements are located at such positions as not to overlap with one another as seen in a direction perpendicular to the cooling surface,

the cooling surface has a recessed portion, and

the recessed portion is located at such a position as to overlap with the joining member provided between the cooling surface and the power module and as not to overlap with any of the plurality of semiconductor elements, as seen in the direction perpendicular to the cooling surface.

### Additional Note 2

The semiconductor device according to additional note 1, wherein

the semiconductor elements include two Semiconductor elements disposed to be adjacent to each other, one of the two semiconductor elements being defined as a first semiconductor element, another one of the two semiconductor elements being defined as a second semiconductor element,

the power module includes
the first semiconductor element,
a first heat spreader having a one-side surface to which the first semiconductor element is electrically connected,
the second semiconductor element,
a second heat spreader disposed side by side with the first heat spreader with a gap therebetween on a same plane, the second heat spreader having a one-side surface to which the second semiconductor element is electrically connected,
an insulating member having a one-side surface to which an other-side surface of the first heat spreader and an other-side surface of the second heat spreader are thermally connected,
a copper plate having a one-side surface to which an other-side surface of the insulating member is thermally connected, and
a sealing resin covering, in a state where an other-side surface of the copper plate is exposed therefrom, the first heat spreader, the second heat spreader, the first semiconductor element, the second semiconductor element, and the insulating member, and

the recessed portion is located, between the first heat spreader and the second heat spreader, at such a position as not to overlap with either of the first heat spreader and the second heat spreader as seen in the direction perpendicular to the cooling surface.

### Additional Note 3

The semiconductor device according to additional note 1 or 2, wherein

the cooling surface is a surface of a plating layer having a solder wettability, and

the recessed portion penetrates the plating layer such that a member on a lower side relative to the plating layer is exposed.

### Additional Note 4

The semiconductor device according to additional note 3, wherein the exposed member on the lower side has a lower solder wettability than the plating layer.

### Additional Note 5

The semiconductor device according to additional note 4, wherein the exposed member on the lower side is made of aluminum or an aluminum alloy.

### Additional Note 6

The semiconductor device according to any one of additional notes 3 to 5, wherein the recessed portion is formed also in the exposed member on the lower side.

### Additional Note 7

The semiconductor device according to any one of additional notes 1 to 6, wherein the recessed portion is a groove extending outward of the joining member provided between the cooling surface and the power module as seen in the direction perpendicular to the cooling surface.

### Additional Note 8

The semiconductor device according to any one of additional notes 1 to 7, wherein

a surface on the joining member side of the power module has a module-side recessed portion, and

the module-side recessed portion is located at such a position as to overlap with the joining member provided between the cooling surface and the power module and as not to overlap with any of the plurality of semiconductor elements, as seen in the direction perpendicular to the cooling surface.

### Additional Note 9

The semiconductor device according to any one of additional notes 1 to 7, wherein

an outer periphery portion of a gap between the cooling surface and the power module has a non-joined region as a region in which the joining member is not provided,

the recessed portion extends, from a region in which the joining member is provided, to the non-joined region as seen in the direction perpendicular to the cooling surface, and

the power module has, in the non-joined region, a protruding portion protruding to the recessed portion side.

### Additional Note 10

The semiconductor device according to additional note 9, wherein

the protruding portion has a height higher than a depth of the recessed portion, and

a gap is present between the protruding portion and an inner surface of the recessed portion.

### Additional Note 11

The semiconductor device according to additional note 9, wherein

a top of the protruding portion is located on an inner side of the recessed portion, and

a gap is present between the protruding portion and an inner surface of the recessed portion.

### Additional Note 12

The semiconductor device according to any one of additional notes 9 to 11, wherein the protruding portion is located at an outer end portion of the non-joined region.

### DESCRIPTION OF THE REFERENCE CHARACTERS

1, 1a, 1b, 1c, 2 first semiconductor element
3 first heat spreader
4 first lead frame
5, 5a, 5b, 5c, 6 second semiconductor element
7, 7a, 7b, 7c second heat spreader
8 second lead frame
9 third lead frame
10 fourth lead frame
11 insulating member
12 copper plate
13 sealing resin
14 cooler
15 joining member
16 plating layer
17, 17a, 17b, 17c, 17d recessed portion
18 recessed-portion surface
19 module-side recessed portion
20 cooling surface
21 protruding portion
21a top
22 bottom of recessed portion
23 non-joined region
100 semiconductor device
101 power module

1. A semiconductor device comprising:
a power module having a plurality of semiconductor elements; and
a cooler having a cooling surface to which the power module is thermally connected via a joining member having a solder material, wherein
the plurality of semiconductor elements are located at such positions as not to overlap with one another as seen in a direction perpendicular to the cooling surface,
the cooling surface has a recessed portion, and
the recessed portion is located at such a position as to overlap with the joining member provided between the cooling surface and the power module and as not to overlap with any of the plurality of semiconductor elements, as seen in the direction perpendicular to the cooling surface.

2. The semiconductor device according to claim 1, wherein
the semiconductor elements include two semiconductor elements disposed to be adjacent to each other, one of the two semiconductor elements being defined as a first semiconductor element, another one of the two semiconductor elements being defined as a second semiconductor element,
the power module includes
the first semiconductor element,
a first heat spreader having a one-side surface to which the first semiconductor element is electrically connected,
the second semiconductor element,
a second heat spreader disposed side by side with the first heat spreader with a gap therebetween on a same plane, the second heat spreader having a one-side surface to which the second semiconductor element is electrically connected,
an insulating member having a one-side surface to which an other-side surface of the first heat spreader and an other-side surface of the second heat spreader are thermally connected,
a copper plate having a one-side surface to which an other-side surface of the insulating member is thermally connected, and
a sealing resin covering, in a state where an other-side surface of the copper plate is exposed therefrom, the first heat spreader, the second heat spreader, the first semiconductor element, the second semiconductor element, and the insulating member, and
the recessed portion is located, between the first heat spreader and the second heat spreader, at such a position as not to overlap with either of the first heat spreader and the second heat spreader as seen in the direction perpendicular to the cooling surface.

3. 3 The semiconductor device according to claim 1, wherein
the cooling surface is a surface of a plating layer having a solder wettability, and
the recessed portion penetrates the plating layer such that a member on a lower side relative to the plating layer is exposed.

4. The semiconductor device according to claim 3, wherein the exposed member on the lower side has a lower solder wettability than the plating layer.

5. The semiconductor device according to claim 4, wherein the exposed member on the lower side is made of aluminum or an aluminum alloy.

6. The semiconductor device according to claim 3, wherein the recessed portion is formed also in the exposed member on the lower side.

7. The semiconductor device according to claim 1, wherein the recessed portion is a groove extending outward of the joining member provided between the cooling surface and the power module as seen in the direction perpendicular to the cooling surface.

8. The semiconductor device according to claim 1, wherein
a surface on the joining member side of the power module has a module-side recessed portion, and
the module-side recessed portion is located at such a position as to overlap with the joining member provided between the cooling surface and the power module and as not to overlap with any of the plurality of semiconductor elements, as seen in the direction perpendicular to the cooling surface.

9. The semiconductor device according to claim 1, wherein
an outer periphery portion of a gap between the cooling surface and the power module has a non-joined region as a region in which the joining member is not provided,
the recessed portion extends, from a region in which the joining member is provided, to the non-joined region as seen in the direction perpendicular to the cooling surface, and
the power module has, in the non-joined region, a protruding portion protruding to the recessed portion side.

10. The semiconductor device according to claim 9, wherein
the protruding portion has a height higher than a depth of the recessed portion, and
a gap is present between the protruding portion and an inner surface of the recessed portion.

11. The semiconductor device according to claim 9, wherein
a top of the protruding portion is located on an inner side of the recessed portion, and
a gap is present between the protruding portion and an inner surface of the recessed portion.

12. The semiconductor device according to claim 9, wherein the protruding portion is located at an outer end portion of the non-joined region.
